(19) United States
(12) Patent Application Publication
(10) Pub. No.: US 2013/0049046 A1
(43) Pub. Date: Feb. 28, 2013

(54) COLOR TUNABLE ORGANIC LIGHT EMITTING DIODE

(71) Applicants: Jaehyun MOON, Daejeon (KR); Hye Yong CHU, Daejeon (KR); Jeong Ik LEE, Gunpo-si (KR); Doo-Hee CHO, Daejeon (KR); Jin Wook SHIN, Incheon (KR); Jun-Han HAN, Daejeon (KR); Jin Woo HUH, Daejeon (KR); Joo Hyun HWANG, Seoul (KR); Chul Woong JOO, Seoul (KR); Byoung Gon YU, Youngdong-gun (KR)

(72) Inventors: Jaehyun MOON, Daejeon (KR); Hye Yong CHU, Daejeon (KR); Jeong Ik LEE, Gunpo-si (KR); Doo-Hee CHO, Daejeon (KR); Jin Wook SHIN, Incheon (KR); Jun-Han HAN, Daejeon (KR); Jin Woo HUH, Daejeon (KR); Joo Hyun HWANG, Seoul (KR); Chul Woong JOO, Seoul (KR); Byoung Gon YU, Youngdong-gun (KR)

(73) Assignee: ELECTRONICS AND TELECOMUNICATIONS RESEARCH INSTITUTE, Daejeon (KR)

(21) Appl. No.: 13/556,558

(22) Filed: Jul. 24, 2012

(30) Foreign Application Priority Data
Aug. 22, 2011 (KR) 10-2011-0083616

(51) Int. Cl. H01L 51/52

(52) U.S. Cl. 257/98; 257/40; 257/E51.018

(57) ABSTRACT

The inventive concept provides an organic light emitting diode that can change its color. A color change is embodied by a micro cavity effect caused by a metal thin film partly formed on a positive pole. The organic light emitting diode includes a positive pole, an organic luminous layer and a negative pole that can be sequentially stacked on a substrate, and further include a metal thin film layer having first strip lines extending in a first direction and being arranged in a second direction crossing the first direction on the positive pole.

### CROSS-REFERENCE TO RELATED APPLICATIONS

This U.S. non-provisional patent application claims priority under 35 U.S.C. §119 of Korean Patent Application No. 10-2011-0083616, filed on Aug. 22, 2011, the entire contents of which are hereby incorporated by reference.

### BACKGROUND

The present inventive concept herein relates to organic light emitting diodes, and more particularly, to an organic light emitting diode that can control its color or its color temperature.

An organic light emitting diode (OLED) is a self light emitting device electrically exciting an organic luminous material to light-emit it. The organic light emitting diode includes a substrate, a positive pole, a negative pole and an organic luminous layer formed between the positive and negative poles. Holes and electrons supplied from the positive and negative poles combine with each other in the organic luminous layer to generate a light which is released into the outside. The organic light emitting diode can release various colors according to the type of material forming the organic luminous layer.

In a white light emitting device among the organic light emitting diodes, a red luminous layer, a green luminous layer and a blue luminous layer are sequentially stacked on the organic luminous layer and colors light-emitted from the red, green and blue luminous layers are mixed to realize a white color. However, to realize a wanted luminous color, there is a difficult that strength of spectrum should be controlled at every wavelength range. As a technical method for this, there is a doping method of adding a material on a luminous layer or a method of adding an organic matter layer on a conventional structure. However, to use those methods, material development should be done and a conventional process should be changed.

### SUMMARY

Embodiments of the inventive concept provide an organic light emitting diode capable of controlling its color temperature. The organic light emitting diode may include a first electrode, an organic luminous layer and a second electrode that are sequentially stacked on a substrate, and a metal thin film layer having a plurality of first strip lines extending in a first direction and being arranged in a second direction crossing the first direction on the first electrode.

### BRIEF DESCRIPTION OF THE FIGURES

Preferred embodiments of the inventive concept will be described below in more detail with reference to the accompanying drawings. The embodiments of the inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art. Like numbers refer to like elements throughout.

FIG. 1 is a cross sectional view for explaining a structure of organic light emitting diode in accordance with some embodiments of the inventive concept.

FIG. 2 is a perspective view for explaining a structure of organic light emitting diode in accordance with an embodiment of the inventive concept.

FIG. 3 is a perspective view for explaining a structure of organic light emitting diode in accordance with another embodiment of the inventive concept.

FIG. 4 is a perspective view for explaining a structure of organic light emitting diode in accordance with still another embodiment of the inventive concept.

FIG. 5 is a graph showing an optical spectrum of organic light emitting diode without a metal thin film layer.

FIG. 6 is a graph showing an optical spectrum of organic light emitting diode on which a metal thin film layer is entirely formed.

FIG. 7 is a graph showing an optical spectrum of organic light emitting diode on which a metal thin film layer is partly formed.

### DETAILED DESCRIPTION OF THE EMBODIMENTS

Embodiments of inventive concepts will be described more fully hereinafter with reference to the accompanying drawings, in which embodiments of the invention are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. In the drawings, the size and relative sizes of layers and regions may be exaggerated for clarity. Like numbers refer to like elements throughout.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

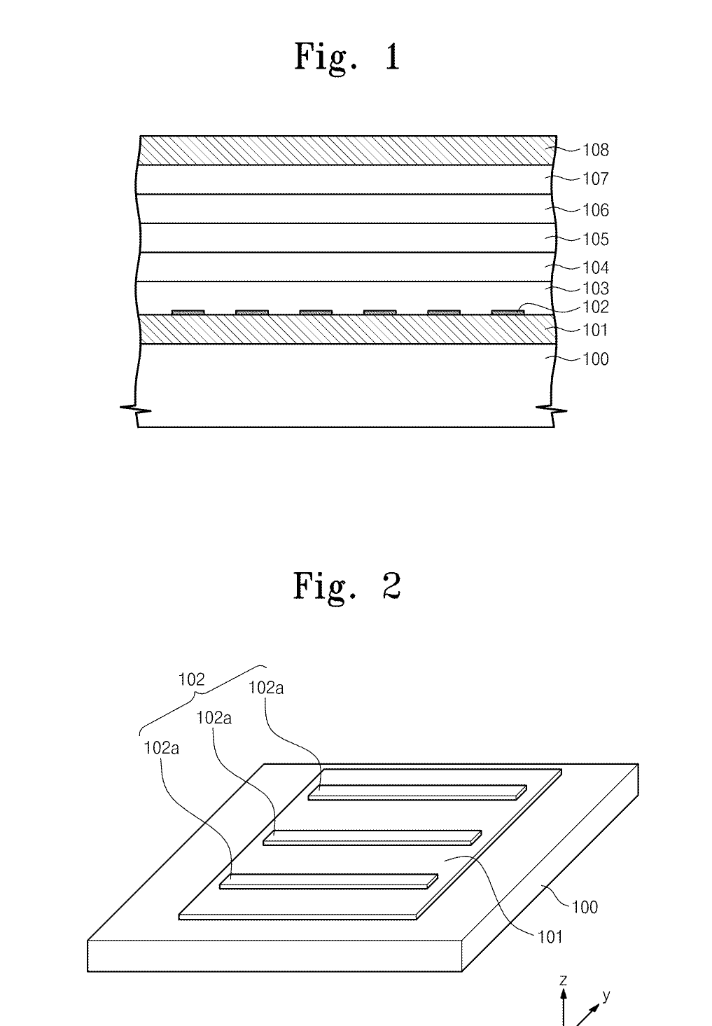

Referring to FIG. 1, a positive pole 101, a hole transfer layer 103, a hole injection layer 104, an organic luminous layer 105, an electron injection layer 106, an electron transfer layer 107 and a negative pole 108 are sequentially formed on a substrate 100. The substrate 100 may include at least one of transparent materials. The substrate 100 may include at least one of glass, quartz or transparent plastic.

The positive pole 101 may be conductive material having transparency. The positive pole 101 may be one of transparent conductive oxides (TCO). The positive pole 101 may be one of indium tin oxide (ITO) and indium zinc oxide (IZO). The positive pole 101 may be an anode.

A metal thin film layer 102 is formed on the positive pole 101. The metal thin film layer 102 may be partly formed on the positive pole 101.

The metal thin film layer 102 may include conductive material different from the positive pole 101. The metal thin film layer 102 may be a thin film including metal, for example, silver (Ag). A thickness of the metal thin film layer 102 may be about 5 nm or less. It is desirable that the metal thin film layer 102 has transparency of about 60% or more.

The hole transfer layer 103, the hole injection layer 104, the organic luminous layer 105, the electron injection layer 106, and the electron transfer layer 107 are sequentially formed on the positive pole 101. The hole transfer layer 103, the hole injection layer 104, the organic luminous layer 105, the electron injection layer 106, and the electron transfer layer 107 may be formed of an organic compound or a combination of metallic complex compound.

The negative pole 108 is formed on the electron transfer layer 107. The negative pole 108 has conductivity. The negative pole 108 may be selected from metal or an optically transparent conductive material. A wavelength of light penetrating the organic light emitting diode may be different depending on a thickness of the metal thin film layer 102.

In the organic light emitting diode in accordance with the inventive concept, the metal thin film layers 102 causing a micro cavity effect are partly formed between the positive pole 101 and the organic luminous layer 105. Accordingly, compared to the spectrum of the organic light emitting diode without metal thin film, that of organic light emitting diode with metal thin film may be changed.

FIG. 2 is a perspective view for explaining a structure of organic light emitting diode in accordance with an embodiment of the inventive concept.

Referring to FIG. 2, the positive pole 101 is formed on the substrate 100 and the metal thin film layer 102 is formed on the positive pole 101. The metal thin film layer 102 may include a plurality of first strip lines 102a extending in a first direction and being arranged in a second direction crossing the first direction on the positive pole 101. The first and second directions may correspond to an x axis and a y axis respectively.

The metal thin film layer 102 is partly formed on the positive pole 101 and thereby a part of the positive pole 101 may be exposed to the organic luminous layer 105. According to an embodiment, a top surface of the first strip line 102a may have a rectangular shape.

The metal thin film layer 102 may be formed by a metal vacuum deposition process, a process using a shadow mask or a sputtering metal deposition process.

A light generated from the organic luminous layer 105 penetrates the metal thin film layer 102 and/or the positive pole 101 to be released to the outside of the substrate 100. Because of a micro cavity effect due to the metal thin film layer 102, a spectrum of light released to the outside of the substrate 100 is different from a spectrum of light not passing through the metal thin film layer 102. A spectrum of light can be changed using the micro cavity effect. That is, a light generated from the organic luminous layer may pass through the metal thin film layer 102 and the positive pole 101 or may directly pass through the positive pole 101 without passing through the metal thin film layer 102. A spectrum of light passing through the metal thin film layer 102 is different from a spectrum of light not passing through the metal thin film layer 102. In this case, a mixed light is generated that a light passing through the metal thin film layer 102 and a light not passing through the metal thin film layer 102 are mixed.

A spectrum of the mixed light is different from a spectrum of light generated from the organic luminous layer. The spectrum of the mixed light may be controlled by changing a shape and a thickness of the metal thin film layer 102.

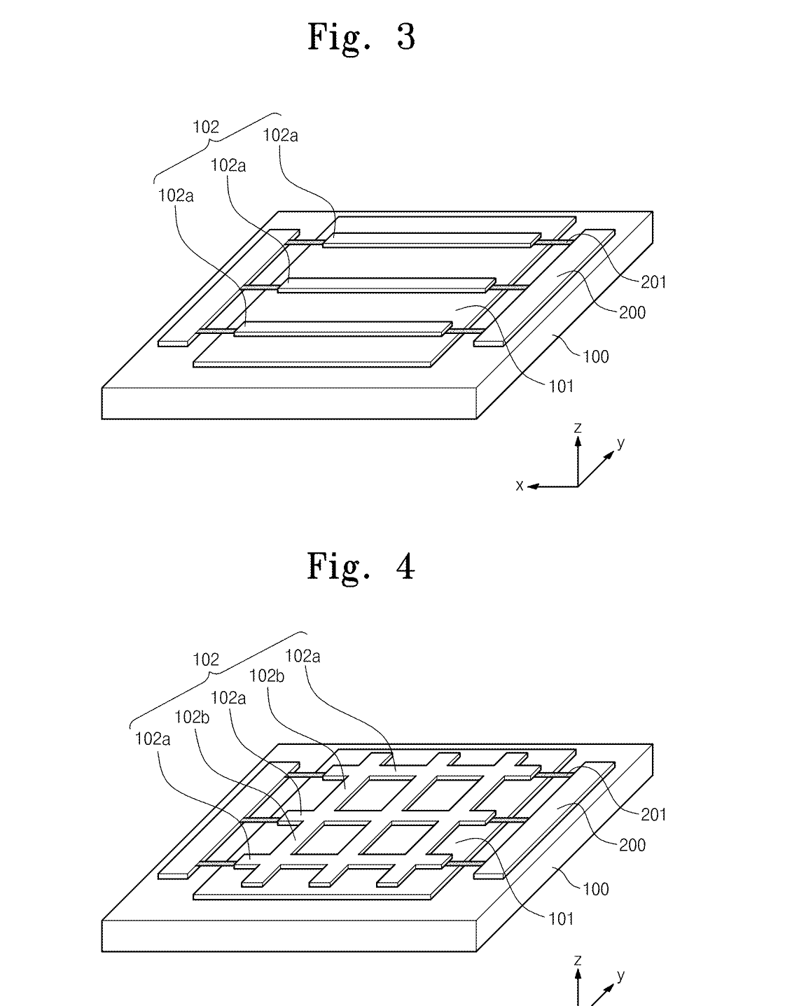

FIG. 3 is a perspective view for explaining a structure of organic light emitting diode in accordance with another embodiment of the inventive concept.

Referring to FIG. 3, the positive pole 101 is formed on the substrate 100 and the metal thin film layer 102 is formed on the positive pole 101. The metal thin film layer 102 may include a plurality of first strip lines 102a extending in a first direction and being arranged in a second direction crossing the first direction on the positive pole 101.

An electrode pad 200 may be disposed on the substrate 100. The electrode pad 200 is formed on the substrate 100 and may be disposed to be spaced apart from the positive pole 101. A voltage may be independently applied to the electrode pad 200. The electrode pad 200 may be electrically connected to the metal thin film layer 102 through an electric wire 201. Thus, a voltage can be applied to the metal thin film layer 102 by the electrode pad 200.

The electrode pad 200 may be formed on positions of the substrate 100 on which the positive pole 101 is not formed and one or a plurality of the electrode pads 200 may be disposed. By disposing the electrode pad 200 on both sides of the substrate 100, a voltage drop that may occur in the metal thin film layer 102 can be prevented.

If a voltage is applied to the metal thin film layer 102, a spectrum of light passing through the metal thin film layer 102 may change and thereby a spectrum of mixed light may change. A spectrum of mixed light can be controlled by changing a voltage being applied to the metal thin film layer 102. The metal thin film layer 102 causes a phase difference of incident light to change a spectrum. If an electricity is applied to the metal thin film layer 102, an optical property of the metal thin film layer 102 is changed by a vibration change of phonon to cause a new phase change with respect to the incident light as compared with the case that an electricity is not applied to the metal thin film layer 102 and thereby a spectrum can be changed.

FIG. 4 is a perspective view for explaining a structure of organic light emitting diode in accordance with still another embodiment of the inventive concept.

Referring to FIG. 4, the positive pole 101 is formed on the substrate 100 and the metal thin film layer 102 is formed on the positive pole 101. The metal thin film layer 102 may include a plurality of first strip lines 102a extending in a first direction and being arranged in a second direction crossing the first direction on the positive pole 101.

The metal thin film layer 102 may further include second strip lines 102b extending in the second direction, being arranged in the first direction and connecting the first strip lines 102a on the positive pole 101. The metal thin film layer 102 may be formed in a checkerboard type on the positive pole 101.

An electrode pad 200 may be further included which is formed on the substrate 100 and is electrically connected to the metal thin film layer 102. The electrode pad 200 may be spaced apart from the positive pole 101. A voltage can be independently applied to the electrode pad 200. The electrode pad 200 may be electrically connected to the metal thin film layer 102 through an electric wire 201. Thus, a voltage can be applied to the metal thin film layer 102 by the electrode pad 200. A spectrum of the mixed light can be controlled by changing a voltage applied to the metal thin film layer 102. The plurality of electrode pads 200 may be symmetrically formed on the substrate 100.

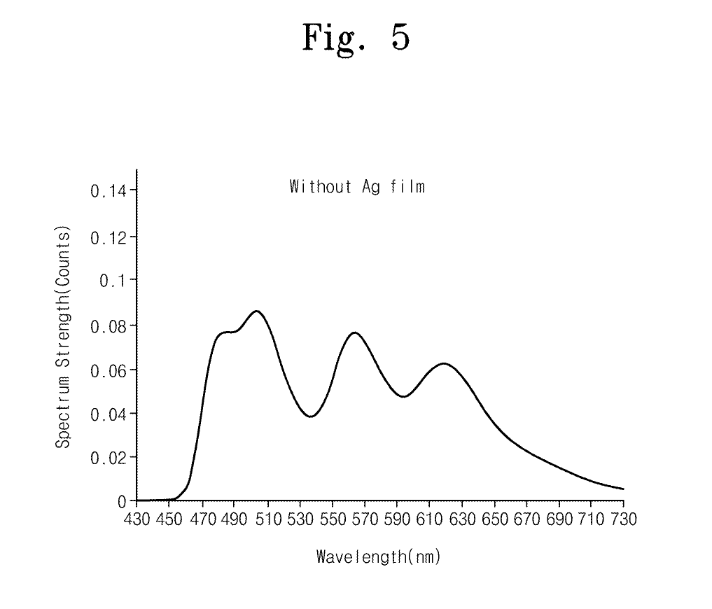

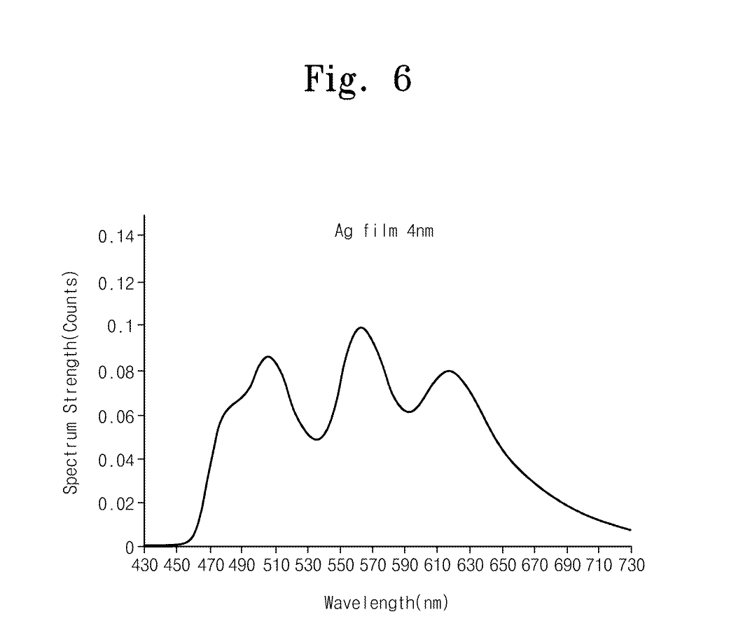

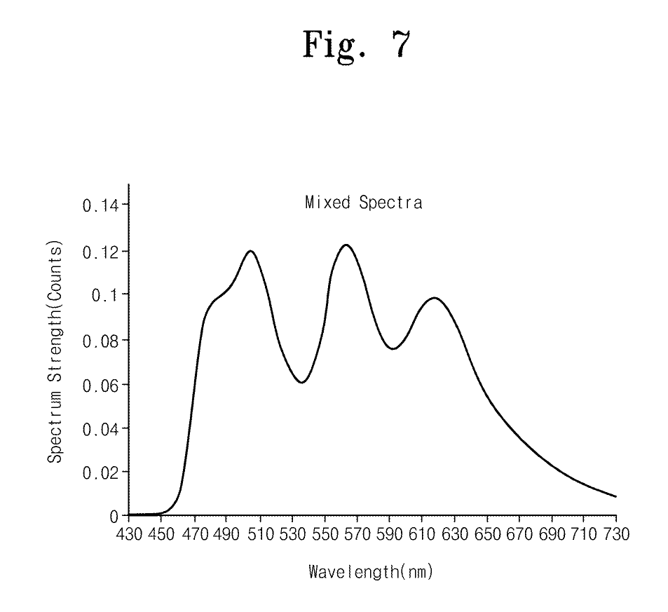

FIG. 5 is a graph showing an optical spectrum of organic light emitting diode without a metal thin film layer. FIG. 6 is a graph showing an optical spectrum of organic light emitting diode on which a metal thin film layer is entirely formed. FIG. 7 is a graph showing an optical spectrum of organic light emitting diode on which a metal thin film layer is partly formed.

Referring to FIGS. 5, 6 and 7, in an organic light emitting diode (OLED) embodied according to an embodiment of the inventive concept, an ITO electrode, a silver (Ag) thin film as the metal thin film layer, the organic luminous layer and an aluminum (Al) electrode may be sequentially stacked on a glass substrate.

A spectrum (FIG. 7) of the organic light emitting diode partly including the metal thin film layer is different from a spectrum (FIG. 5) of the organic light emitting diode not including the metal thin film layer and a spectrum (FIG. 6) of the organic light emitting diode entirely including the metal thin film layer. The spectrum (FIG. 7) has stronger spectrum strength at a specific wavelength range. As an illustration, a spectrum strength of blue color having 510 nm wavelength range in the organic light emitting diode partly including the metal thin film layer may be stronger than that in the organic light emitting diode not including the metal thin film layer.

In a white color OLED embodied by mixture of blue, green and red colors, spectrum strength of blue color wavelength range may be weak. However, the OLDE in accordance with the inventive concept can increase spectrum strength of blue color wavelength range by partly forming the metal thin film layer on the positive pole. That is, the OLED in accordance with the inventive concept can cause a micro cavity effect due to the metal thin film layer to generate a mixed spectrum, can increase spectrum strength of specific wavelength range and can control a color or a color temperature by controlling a shape and a thickness of the metal thin film layer or controlling a voltage applied to the metal thin film layer.

The OLED in accordance with the inventive concept partly has a metal thin film layer causing a micro cavity effect between a negative pole and an organic luminous layer. Thus, a light which passed through the metal thin film layer has a different spectrum distribution from a light generated from the organic luminous layer. A light which passed through the metal thin film layer and a light which did not passed through the metal thin film layer are mixed to generate a light having a new spectrum and the light is released to the outside.

The OLED in accordance with the inventive concept can control a spectrum of light passing through the metal thin film layer by including an electrode pad that can independently address a voltage to the metal thin film layer. Thus, a color variable OLED is provided which can control a color or a color temperature of light being released.

What is claimed is:

1. An organic light emitting diode comprising:
a first electrode, an organic luminous layer and a second electrode that are sequentially stacked on a substrate; and
a metal thin film layer having a plurality of first strip lines extending in a first direction and being arranged in a second direction crossing the first direction on the first electrode.

2. The organic light emitting diode of claim 1, wherein a top surface of each of the first strip lines has a rectangular shape.

3. The organic light emitting diode of claim 1, wherein the metal thin film layer further includes second strip lines extending in the second direction, being arranged in the first direction and connecting the first strip lines on the first electrode.

4. The organic light emitting diode of claim 1, wherein the metal thin film layer causes a micro cavity effect changing a spectrum of light generated from the organic luminous layer.

5. The organic light emitting diode of claim 1, wherein the metal thin film layer includes Ag, Au, Cu, Pt, Ni, Cr, Pd, Mg, Cs, Ca, Sn, Sb, Pb or combinations thereof.

6. The organic light emitting diode of claim 1, wherein the metal thin film layer includes a metal having a transparency of 60% or more and a thickness of 2 nm through 5 nm.

7. The organic light emitting diode of claim 1, further comprising an electrode pad which is formed on the substrate and is electrically connected to the metal thin film layer, wherein the electrode pad is spaced apart from the first electrode.

8. The organic light emitting diode of claim 7, wherein the electrode pad is formed on positions of the substrate on which the first electrode is not formed.

9. The organic light emitting diode of claim 7, wherein the electrode pad is symmetrically formed to be the plural number on the substrate.

10. The organic light emitting diode of claim 7, wherein spectrum strength of light being released is controlled at every wavelength range by applying a voltage to the metal thin film layer through the electrode pad.

11. The organic light emitting diode of claim 1, wherein the organic luminous layer further includes an auxiliary layer, wherein the auxiliary layer includes at least one of a hole injection layer, a hole transfer layer, an electron transfer layer and an electron injection layer.
